(19) United States
(12) Patent Application Publication
(10) Pub. No.: US 2005/0183592 A1
(43) Pub. Date: Aug. 25, 2005

(54) Screen printing apparatus and screen printing method

(75) Inventors: Yuji Otake, Fukuoka-ken (JP); Takaaki Sakaue, Fukuoka-ken (JP); Tetsuya Tanaka, Fukuoka-ken (JP)

Correspondence Address: PEARNE & GORDON LLP, 1801 EAST 9TH STREET, SUITE 1200, CLEVELAND, OH, 44114-3108, US

(73) Assignee: Matsushita Electric Industrial Co., Ltd., Osaka (JP)

(21) Appl. No.: 11/061,913

(22) Filed: Feb. 18, 2005

(30) Foreign Application Priority Data
Feb. 20, 2004 (JP) 2004-044275

(51) Int. Cl. B41L 13/18; B05C 17/06; H01L 21/48; B41C 1/00

(52) U.S. Cl. 101/123; 101/126; 101/129; 101/401.1; 101/483

(57) ABSTRACT

In screen printing for printing cream-like solder on a board 7 through through-holes of a mask plate 12, removal of the board 7 from a lower surface of the mask plate 12 is performed in such a manner that the board 7 is moved down at a first descending velocity V1 as a lower velocity during an initial stroke S1 of from a state where the removal of the board 7 starts to a state where the board 7 is removed from the mask plate 12 so that the distance between the upper surface of the board 7 and the lower surface of the mask plate 12 reaches a predetermined value set to be in a range of from a half to twice as large as the thickness of the mask plate 12, and that the board 7 is moved down at a second descending velocity V2 as a higher velocity after the initial stroke S1. Accordingly, even in the case where solder apt to vary according to the passage of time is used, good removability and stable print quality can be secured.

### BACKGROUND OF THE INVENTION

The present invention relates to a screen printing apparatus and a screen printing method for printing cream-like solder on a board.

A method using screen printing is known as a solder supply method used for soldering electronic parts to a board. In this method, there is used a screen printing apparatus having a screen printing mechanism in which cream-like solder is printed in an electrode surface of a board through pattern holes provided in a mask plate and in which a squeegee is slid on an upper surface of the mask plate in the condition that the board is brought into contact with a lower surface of the mask plate (e.g. see Patent Document JP-A-8-11283/(1996)).

To keep print quality good in screen printing, good packability for packing cream-like solder in the pattern holes surely, and good removability for removing the cream-like solder from the pattern holes without shape lost at the time of removal of the mask plate from the lower surface of the board after packing of the cream-like solder are required. Therefore, in the screen printing operation, various attempts have been made to optimize the operating speed and operating pattern in accordance with the property of solder in use when the board is removed from the mask plate. For example, according to Patent Document JP-A-8-11283, the speed of removing the board from the mask plate is set to be low until the board is removed from the mask plate sufficiently.

From the point of view of diversification in the purpose of use of electronic parts and environmental conservation, solder different in kind from heretofore usually used solder has been used recently for soldering of electronic parts. That is, lead-free solder little containing any harmful solder component has been used widely by the request of environmental conservation. On the other hand, on-vehicle solder such as acrylic solder has been used in on-vehicle electronic appliances.

The property of such solder varies during use even in the case where the solder is taken out from one pot and used continuously because the progress of deterioration of the solder with the passage of time is rapid compared with the heretofore used solder. For this reason, even in the case where the removing operation pattern is optimized in accordance with the property of solder in advance, failure in removing may occur because the removing operation pattern cannot agree with the optimum pattern any more if change in property such as increase in viscosity is caused by deterioration with the passage of time. As described above, in the screen printing according to the background art, there is a problem that it is difficult to secure good removability when solder apt to vary according to the passage of time is used.

### SUMMARY OF THE INVENTION

Therefore, an object of the invention is to provide a screen printing apparatus and a screen printing method in which good removability and stable print quality can be secured even in the case where solder apt to vary accordance with the passage of time is used.

The screen printing apparatus according to the invention is a screen printing apparatus for bringing a board into contact with a lower surface of a mask plate having through-holes formed therein and printing cream-like solder on the board through the through-holes, including a board bearing portion for bearing and retaining the board, a removing unit for moving the board bearing portion up and down to thereby separate the board from the lower surface of the mask plate, and a removing control unit for controlling the removing unit, wherein the removing control unit controls the removing unit so that the board bearing portion is moved down at a first removing velocity during a stroke of from a state where the board is in contact with the lower surface of the mask plate to a state where the distance between an upper surface of the board and the lower surface of the mask plate reaches a predetermined value set to be in a range of from a half to twice as large as the thickness of the mask plate, and that the board bearing portion is moved down at a second removing velocity higher than the first removing velocity after the stroke.

The screen printing method according to the invention is a screen printing method for bringing a board into contact with a lower surface of a mask plate having through-holes formed therein and printing cream-like solder on the board through the through-holes, including the steps of: bringing the board into contact with the lower surface of the mask plate (mask mounting step); moving squeegees on the mounted mask plate to thereby pack solder in the through-holes (packing step); and removing the board from the lower surface of the mask plate (removing step), wherein the removing step is carried out in such a manner that the board bearing portion is moved down at a first removing velocity during a stroke of from a state where the board is in contact with the lower surface of the mask plate to a state where the distance between an upper surface of the board and the lower surface of the mask plate reaches a predetermined value set to be in a range of from a half to twice as large as the thickness of the mask plate, and that the board bearing portion is moved down at a second removing velocity higher than the first removing velocity after the stroke.

According to the invention, the removing step for removing the board from the lower surface of the mask plate is carried out in such a manner that the board bearing portion is moved down at a first removing velocity during a stroke of from a state where the board is in contact with the lower surface of the mask plate to a state where the distance between an upper surface of the board and the lower surface of the mask plate reaches a predetermined value set to be in a range of from a half to twice as large as the thickness of the mask plate, and that the board bearing portion is moved down at a second removing velocity higher than the first removing velocity after the stroke. Accordingly, even in the case where solder apt to vary according to the passage of time is used, good removability and stable print quality can be secured.

### BRIEF DESCRIPTION OF THE DRAWINGS

FIG. 1 is a side sectional view of a screen printing apparatus according to an embodiment of the invention;

FIG. 2 is a side sectional view of a screen printing apparatus according to an embodiment of the invention;

FIGS. 3A to 3E are views for explaining a screen printing operation of the screen printing apparatus according to an embodiment of the invention; and

FIGS. 4A to 4D are views for explaining a removing operation included in the screen printing operation in the embodiment of the invention.

### DETAILED DESCRIPTION OF THE PREFERRED EMBODIMENTS

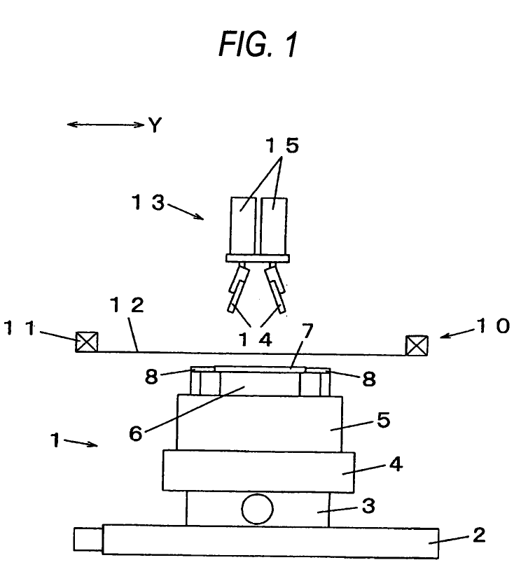

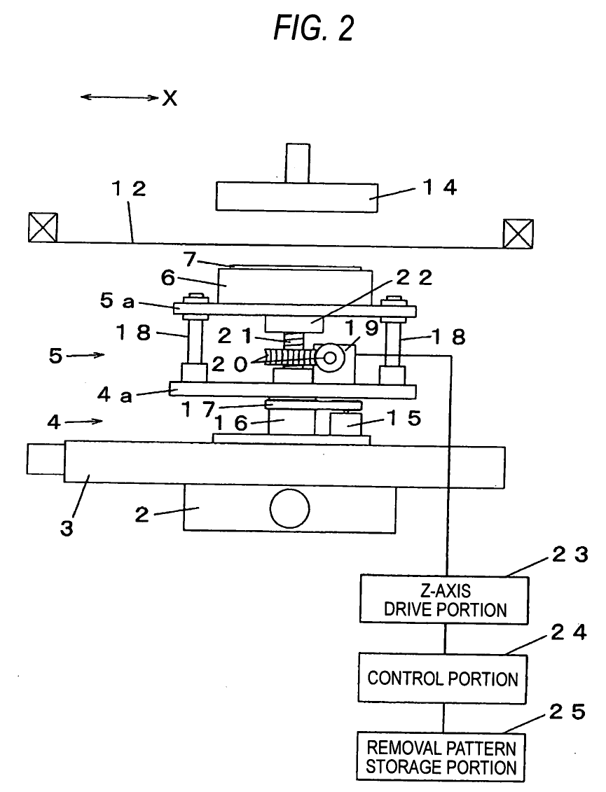

An embodiment of the invention will be described below with reference to the drawings. Referring first to FIGS. 1 and 2, the structure of the screen printing apparatus will be described. The screen printing apparatus has a function for bringing a board into contact with a lower surface of a mask plate having through-holes formed therein and printing cream-like solder on the board through the through-holes. In FIG. 1, a board positioning portion 1 is configured so that a Y-axis table 2, an X-axis table 3, a θ-axis table 4 and a Z-axis table 5 are layered. Aboard bearing portion 6 for bearing and retaining a board 7 as a subject of printing is disposed on the Z-axis table 5. The board 7 on the board bearing portion 6 is clamped by dampers 8.

As shown in FIG. 2, the θ-axis table 4 has a rotation plate 4a which rotates by θ around a vertical axis on the basis of a shaft portion 16. When a θ motor 15 drives the shaft portion 16 to rotate through a belt 17, the rotation plate 4a rotates by θ around the vertical axis. The Z-axis table 5 has an elevating plate 5a which moves up and down while guided by slide shafts 18. A feed screw 21 provided vertically is thread-engaged with a nut 22 fixed to the elevating plate 5a. The feed screw 21 is driven to rotate by a Z motor 19 through a worm mechanism 20. When the Z motor 19 is driven, the elevating plate 5a moves up and down so that the board 7 on the board bearing portion 6 moves up and down.

The Z motor 19 is driven by a Z-axis drive portion 23. The Z-axis drive portion 23 is controlled by a control portion 24. A removing operation pattern which will be described later is stored in a removal pattern storage portion 25. When the control portion 24 controls the Z-axis drive portion 23 on the basis of the removing operation pattern in a screen printing operation, a removing operation for removing the board 7 from the mask plate 12 can be carried out in a predetermined operating pattern. Accordingly, the Z motor 19, the feed screw 21, the nut 22 and the Z-axis drive portion 23 constitute a removing unit for moving the board bearing portion 6 up and down to thereby remove the board 7 from the lower surface of the mask plate 12 whereas the control portion 24 constitutes a removal control unit for controlling the removing unit.

A screen printing portion 10 is disposed above the board positioning portion 1. The screen printing portion 10 has the mask plate 12 held in a frame-shaped holder 11. A squeegee unit 13 is disposed above the mask plate 12 so that the squeegee unit 13 can be moved in the Y direction by a squeegee moving table (not shown). As shown in FIG. 1, the squeegee unit 13 has a pair of squeegees 14 moved up and down by cylinders 15. When the cylinders 15 are driven in the condition that the board 7 is brought into contact with the lower surface of the mask plate 12, the squeegees 14 move down so that lower end portions of the squeegees 14 come into contact with the upper surface of the mask plate 12.

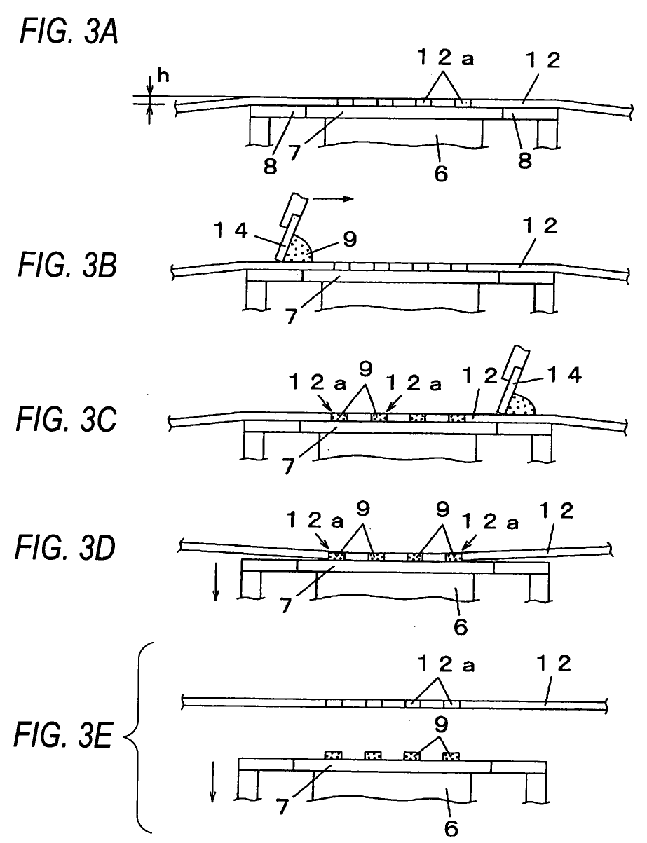

Referring next to FIGS. 3A to 3E, the screen printing operation will be described. Screen printing performed here is printing of cream-like solder in order to form solder bumps on the board 7. A thin mask plate 12 having pattern holes 12a (through-holes) formed at high density is used. Printing due to this type mask plate is very difficult. Particularly in the removing operation after squeegeeing, it is difficult to perform uniform removal on the whole range of the board.

That is, tackiness at the time of removal is high because the pattern holes are formed at high density. On the other hand, the mask plate is apt to be pulled down at the time of the removing operation of moving the board down because the mask plate per se is so thin as to be apt to be bent. As a result, a difference in removal timing is generated between the outer circumferential portion of the board and the center portion of the board to thereby make it difficult to optimize the uniform removal condition. Screen printing shown in this embodiment is applied to such difficult screen printing for forming solder bumps, so that keeping removability good and uniform is achieved by the following method.

First, as shown in FIG. 3A, the board 7 on the board bearing portion 6 is clamped by the dampers 8 so as to be retained. The Z-axis table 5 is driven so that the board bearing portion 6 is moved up. As a result, the board 7 moves up and comes into contact with the lower surface of the mask plate 12 (mask mounting step). On this occasion, the upper surface of the board 7 is moved up to a position higher by a predetermined toss margin h than a normal height position of the lower surface of the mask plate 12 so that a state of contact between the board 7 and the mask plate 12 is set as the upper surface of the board 7 is tossed up.

Then, as shown in FIG. 3B, the squeegees 14 are brought into contact with the mask plate 12. The squeegees 14 are moved horizontally in the condition that cream-like solder 9 is supplied onto the mask plate 12. By the squeegeeing operation, the solder 9 is packed in each pattern hole 12a as shown in FIG. 3C (packing step).

Then, a removing operation is carried out. That is, the Z-axis table 5 is driven so that the board bearing portion 6 is moved down. The board 7 is removed from the lower surface of the mask plate 12 while the solder 9 packed in the pattern holes 12a is deposited on the board 7. On this occasion, as shown in FIG. 3D, the separation of the board 7 and the mask plate 12 from each other starts at the outer circumferential portion of the board 7. In the state where the removal of the outer circumferential portion starts, the center portion of the board 7 still adheres to the mask plate 12.

When the board bearing portion 6 is further moved down, removal on the whole range of the board 7 is performed as shown in FIG. 3E. That is, the mask plate 12 is removed from the upper surface of the board 7 stepwise (removing step). Thus, the screen printing operation for printing the solder 9 on the upper surface of the board 7 through the pattern holes 12a is completed.

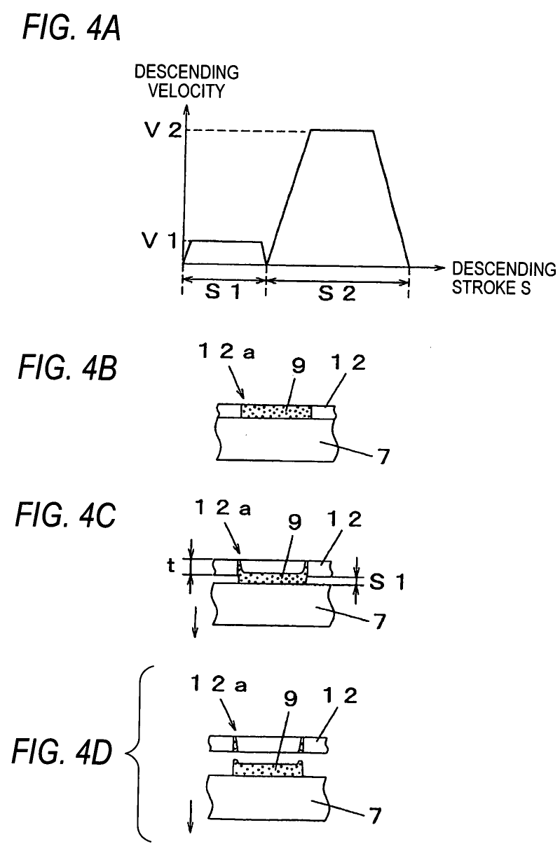

Referring next to FIGS. 4A to 4D, the operation pattern of the removing operation included in the screen printing operation will be described. FIG. 4A shows a velocity pattern of the board bearing portion 6 driven by the Z motor 19 in the removing operation. In FIG. 4A, the removing operation pattern is defined on the basis of the relation between descending stroke S and descending velocity V (removing velocity) which show the amount of descending when the board bearing portion 6 is moved down.

As shown in the removing operation pattern, in the removing step in the screen printing method, the descending velocity is set to be a low velocity (e.g. about 0.1 min/s) as a first descending velocity V1 (first removing velocity) so that the board bearing portion 6 is moved down slowly until the descending stroke reaches an initial stroke S1 (which will be described later) after the start of the removing operation. When the descending stroke reaches the initial stroke S1, the descending velocity is once turned back to zero and then increased again so that the board bearing portion 6 is moved down at a second descending velocity V2 (second removing velocity) (e.g. about 5 mm/s) higher than the first descending velocity V1. Thus, the board bearing portion 6 moves down by a latter stroke S2 and stops in a descending position.

That is, the solder 9 descends at a low velocity (first descending velocity V1) during a stroke of from a state where the solder 9 is packed in the pattern holes 12a as shown in FIG. 4B to a state where the upper surface of the board 7 is separated by the initial stroke S1 from the lower surface of the mask plate 12 as shown in FIG. 4C. On this occasion, the initial stroke S1 is set in accordance with the thickness t of the mask plate 12. In this embodiment, the initial stroke S1 is set to be in a range of from a half to twice as large as the thickness t (preferably, in a range of from a half to 9/10 and, more preferably, in a range of from ⅔ to ¾ as large as the thickness t).

Because the descending velocity of the board 7 is a low velocity of the order of 0.1 mm/s during the initial stroke S1, part of the solder 9 located so as to be in contact with side wall surfaces of the pattern holes 12a shows a strong tendency to remain in the pattern holes 12a while the part of the solder 9 is deposited on the side wall surfaces of the pattern holes 12a after descending of the board 7 starts, as shown in FIG. 4C. The remaining part of the solder 9 is connected to part of the solder 9 printed on the upper surface of the board 7 and descending together with the board 7, by cream-like solder 9 stretched so as to be hung down. This tendency is little affected by the property of the solder 9, so that the solder 9 shows this tendency on a wide viscosity range.

FIG. 4D shows a state of the solder 9 in the latter stroke S2. That is, because the descending velocity is rapidly increased from the first descending velocity V1 as a lower velocity to the second descending velocity V2 in the timing shown in FIG. 4A, the solder 9 part of which is deposited on the side wall surfaces of the pattern holes 12a and connected to part of the solder 9 on the board 7 in FIG. 4C is torn off by impulsive tensile force at the time of increasing the velocity. As a result, removal is performed so that large part of the solder 9 packed in the pattern holes 12a in FIG. 4B descends together with the board 7 while the other part of the solder 9 remains on the side wall surfaces of the pattern holes 12a.

That is, in the removing operation pattern, the removing unit is controlled so that the board bearing portion 6 is moved down at the first removing velocity during a stroke of from a state where the board 7 is in contact with the lower surface of the mask plate 12 to a state where the upper surface of the board 7 is separated by a determined distance (set to be in a range of from a half to twice as large as the thickness of the mask plate 12) from the lower surface of the mask plate 12, and that the board bearing portion 6 is then moved down at the second removing velocity higher than the first removing velocity.

Accordingly, even in the case where the viscosity of the solder 9 used for printing varies according to the passage of time, the removability is little affected by the state of the viscosity. In any case, the removability can be kept within an allowance. Accordingly, even in the case where solder apt to vary according to the passage of time, such as lead-free solder or acrylic solder, is used, good removability and stable print quality can be secured.

Although setting the initial stroke S1 to be as small as possible is advantageous from the aspect of tact time, it is preferable that the distance between the board 7 and the lower surface of the mask plate 12 is not smaller than a certain value so that the shape of the solder 9 printed by tearing off the connected-state solder 9 as described above is prevented as sufficiently as possible from being lost. Therefore, in practice, the initial stroke SI is decided after allowed tact time and required print quality are considered while compared with each other.

This application is based upon and claims the benefit of priority of Japanese Patent Application No. 2004-044275 filed on Feb. 20, 2004, the contents of which are incorporated herein by reference in its entirety.

The screen printing apparatus and the screen printing method according to the invention have an effect that good removability and stable print quality can be secured. They are useful for the purpose of printing solder apt to vary according to the passage of time on a board.

1. A screen printing apparatus for bringing a board into contact with a lower surface of a mask plate having through-holes formed therein and printing cream-like solder on said board through said through-holes, comprising:
a board bearing portion for bearing and retaining said board;
a removing unit for moving said board bearing portion up and down to thereby separate said board from said lower surface of said mask plate; and
a removing control unit for controlling said removing unit,
wherein said removing control unit controls said removing unit so that said board bearing portion is moved down at a first removing velocity during a stroke of from a state where said board is in contact with said lower surface of said mask plate to a state where the distance between an upper surface of said board and said lower surface of said mask plate reaches a predetermined value set to be in a range of from a half to twice as large as the thickness of said mask plate, and that said board bearing portion is moved down at a second removing velocity higher than said first removing velocity after said stroke.

2. A screen printing apparatus according to claim 1, wherein the removing velocity is once turned back to zero after the distance between said upper surface of said board and said lower surface of said mask plate reaches said predetermined value.

3. A screen printing apparatus according to claim 1, wherein said solder is either of lead-free solder and acrylic solder being apt to vary according to the passage of time.

4. A screen printing method for bringing a board into contact with a lower surface of a mask plate having through-holes formed therein and printing cream-like solder on said board through said through-holes, comprising the steps of:
bringing said board into contact with said lower surface of said mask plate (mask mounting step);
moving squeegees on said mounted mask plate to thereby pack solder in said through-holes (packing step); and
removing said board from said lower surface of said mask plate (removing step),
wherein said removing step is carried out in such a manner that said board bearing portion is moved down at a first removing velocity during a stroke of from a state where said board is in contact with said lower surface of said mask plate to a state where the distance between an upper surface of said board and said lower surface of said mask plate reaches a predetermined value set to be in a range of from a half to twice as large as the thickness of said mask plate, and that said board bearing portion is moved down at a second removing velocity higher than said first removing velocity after said stroke.

5. A screen printing method according to claim 4, wherein the removing velocity is once turned back to zero after the distance between said upper surface of said board and said lower surface of said mask plate reaches said predetermined value.

6. A screen printing method according to claim 4, wherein a part of solder located so as to be in contact with side wall surfaces of said through-holes of said mask plate and a part of solder printed on said upper surface of said board and descending together with said board are connected to each other by solder stretched so as to be hung down until the distance between said upper surface of said board and said lower surface of said mask plate reaches said predetermined value; and
said connected solder is torn off when the removing velocity is increased to said second removing velocity.

7. A screen printing method according to claim 4, wherein said solder is either of lead-free solder and acrylic solder being apt to vary according to the passage of time.

8. A screen printing apparatus according to claim 1, wherein said predetermined value is set in a range of from a half to 9/10 as large as the thickness of said mask plate.

9. A screen printing apparatus according to claim 1, wherein said predetermined value is set in a range of from ⅔ to ¾ as large as the thickness of said mask plate.

10. A screen printing apparatus according to claim 1, wherein said first removing velocity is about 0.1 mm/s.

11. A screen printing apparatus according to claim 1, wherein said second removing velocity is about 5 mm/s.

12. A screen printing method according to claim 4, wherein said predetermined value is set in a range of from a half to 9/10 as large as the thickness of said mask plate.

13. A screen printing method according to claim 4, wherein said predetermined value is set in a range of from ⅔ to ¾ as large as the thickness of said mask plate.

14. A screen printing method according to claim 4, wherein said first removing velocity is about 0.1 mm/s.

15. A screen printing method according to claim 4, wherein said second removing velocity is about 5 mm/s.
